(19) United States
(12) Patent Application Publication
(10) Pub. No.: US 2024/0355533 A1
(43) Pub. Date: Oct. 24, 2024

(54) COIL, INDUCTOR COMPONENT, AND INDUCTOR ARRAY

(71) Applicant: Murata Manufacturing Co., Ltd., Nagaokakyo-shi (JP)

(72) Inventors: Yoshimitsu USHIMI, Nagaokakyo-shi (JP); Koshi HIMEDA, Nagaokakyo-shi (JP); Kenji NISHIYAMA, Nagaokakyo-shi (JP); Hidehiko SASAKI, Nagaokakyo-shi (JP); Nobuyoshi ADACHI, Nagaokakyo-shi (JP)

(21) Appl. No.: 18/762,018

(22) Filed: Jul. 2, 2024

Related U.S. Application Data
(63) Continuation of application No. PCT/JP2023/002473, filed on Jan. 26, 2023.

(30) Foreign Application Priority Data
Feb. 7, 2022 (JP) 2022-017328

(51) Int. Cl. H01F 27/28; H01F 27/24; H01F 27/32

(52) U.S. Cl. CPC H01F 27/2823; H01F 27/24; H01F 27/324

(57) ABSTRACT

A coil that includes: a coil wire spirally wound along an axis; and an insulator that covers at least a portion of the coil wire. In a cross section including the axis, the insulator includes: a first insulation portion in contact with a first end surface of the coil wire on a first side in a direction of the axis of the coil wire, a second insulation portion in contact with a second end surface of the coil wire on a second side in the direction of the axis of the coil wire, and a third insulation portion between adjacent turns in the direction of the axis of the coil wire. At least one of a first thickness of the first insulation portion and a second thickness of the second insulation portion is thinner than half of a third thickness of the third insulation portion.

### CROSS REFERENCE TO RELATED APPLICATIONS

The present application is a continuation of International application No. PCT/JP2023/002473, filed Jan. 26, 2023, which claims priority to Japanese Patent Application No. 2022-017328, filed Feb. 7, 2022, the entire contents of each of which are incorporated herein by reference.

### TECHNICAL FIELD

The present disclosure relates to a coil, an inductor component, and an inductor array.

### BACKGROUND ART

In recent years, size reduction of electronic devices

such as game machines and mobile phones has been accelerated, and as a result, there is an increasing demand for a reduced and thinner size of elements using various coils of inductors mounted ion electronic devices.

In addition, various elements used in a power supply line that supplies power to a load such as a processor are disposed in the vicinity of the load. In this manner, a loss can be reduced. Therefore, for example, since the elements need to be incorporated into a substrate on which the load is mounted, there is a strong demand for a further reduced and thinner size.

In view of this background, there is a demand for a thinner coil used in an element such as an inductor or a transformer.

In the related art, Japanese Unexamined Patent Application Publication No. 2010-123864 (Patent Document 1) discloses the coil. The coil is formed by spirally winding a flat conductor wire formed of a copper plate covered with an insulation coating film along an axis.

### SUMMARY OF THE DISCLOSURE

However, in the coil in the related art, a length of the coil in a direction of an axis cannot be shortened due to an insulation coating film covering a copper plate of the flat conductor wire, and thinning of the coil is hindered. When the length of the coil in the direction of the axis needs to be shortened, the number of turns of the coil has to be reduced, thereby causing a problem that performance of the coil is degraded.

Therefore, the present disclosure aims to provide a coil, an inductor component, and an inductor array which can become thinner.

According to one aspect of the present disclosure, in order to solve the above-described problem, there is provided a coil including: a coil wire spirally wound along an axis;

and an insulator that covers at least a portion of the coil wire. In a cross section including the axis, the insulator includes: a first insulation portion in contact with a first end surface of the coil wire on a first side in a direction of the axis of the coil wire, a second insulation portion in contact with a second end surface of the coil wire on a second side in the direction of the axis of the coil wire, and a third insulation portion between adjacent turns in the direction of the axis of the coil wire. At least one of a first thickness of the first insulation portion and a second thickness of the second insulation portion is thinner than half of a third thickness of the third insulation portion.

Here, when the coil wire includes a plurality of coil conductor layers laminated along the axis, one surface of the coil conductor layer located on one side in the direction of the axis is referred to as a “first end surface”, and the other surface of the coil conductor layer located on the other side in the direction of the axis is referred to as a “second end surface”. In addition, when the coil wire is formed to continuously proceed along the axis, a surface of the coil wire which faces one side in the direction of the axis when viewed from one side in the direction of the axis is referred to as a “first end surface”, and a surface of the coil wire which faces the other side in the direction of the axis when viewed from the other side in the direction of the axis is referred to as a “second end surface”.

According to the aspect, at least one thickness in the thickness of the first insulation portion and the thickness of the second insulation portion can become thinner. Therefore, the thickness of the insulator can become thinner, a length of the coil in the direction of the axis can be shortened, and the coil can become thinner.

In addition, according to another aspect of the present disclosure, there is provided a coil including: a coil wire spirally wound along an axis; and an insulator that covers at least a portion of the coil wire. In a cross section including the axis, the insulator includes: a third insulation portion between adjacent turns in a direction of the axis of the coil wire without being in contact with at least one of a first end surface on a first side of the coil wire in the direction of the axis and a second end surface on a second side of the coil wire in the direction of the axis.

According to the aspect, the insulator does not come into contact with at least one of the first end surface and the second end surface of the coil wire. Therefore, the thickness of the insulator can become thinner, and the length of the coil in the direction of the axis can be shortened.

Preferably, in one embodiment of the coil, in the cross section including the axis, the coil wire may include a first wiring portion and a second wiring portion which form adjacent turns of the coil wire in the direction of the axis. A thickness Ti3 of the third insulation portion between the first wiring portion and the second wiring portion may be thinner than a thickness T1 of the first wiring portion, and may be thinner than a thickness T2 of the second wiring portion.

According to the embodiment, the thickness of the third insulation portion can become thinner. Therefore, the thickness of the insulator can become thinner, and the length of the coil in the direction of the axis can be shortened.

Since the thickness of the third insulation portion can become thinner, a connection conductor layer that electrically connects the first wiring portion and the second wiring portion is provided, and when the connection conductor layer penetrates the third insulation portion, the thickness of the connection conductor layer can become thinner. In this manner, electrical resistance of the connection conductor layer can be reduced, and electrical resistance of the coil wire can be reduced.

Since the thickness of the first wiring portion and the thickness of the second wiring portion can become thicker, the thickness of the coil wire can become thicker, and the electrical resistance of the coil wire can be reduced.

Preferably, in one embodiment of the coil, in the cross section including the axis, the coil wire may include a first wiring portion and a second wiring portion which form adjacent turns of the coil wire in the direction of the axis. A width Wi3 of the third insulation portion between the first wiring portion and the second wiring portion may be equal to or less than 1.5 times a width W1 of the first wiring portion, and may be equal to or less than 1.5 times a width W2 of the second wiring portion.

According to the embodiment, since the width of the third insulation portion can be narrowed, it is possible to reduce a possibility that a magnetic flux of the coil is blocked by the third insulation portion.

Preferably, in one embodiment of the coil, in the cross section including the axis, the coil wire may include a first wiring portion and a second wiring portion which form adjacent turns of the coil wire in the direction of the axis. A ratio Ti3/(Tc+Ti3) between a sum Tc of a thickness T1 of the first wiring portion and a thickness T2 of the second wiring portion and a thickness Ti3 of the third insulation portion between the first wiring portion and the second wiring portion may be equal to or lower than 30%.

According to the embodiment, the thickness of the third insulation portion can become thinner. Therefore, the thickness of the insulator can become thinner, and the length of the coil in the direction of the axis can be shortened.

Since the thickness of the third insulation portion can become thinner, a connection conductor layer that electrically connects the first wiring portion and the second wiring portion is provided, and when the connection conductor layer penetrates the third insulation portion, the thickness of the connection conductor layer can become thinner. In this manner, electrical resistance of the connection conductor layer can be reduced, and electrical resistance of the coil wire can be reduced.

Since the thickness of the first wiring portion and the thickness of the second wiring portion can become thicker, the thickness of the coil wire can become thicker, and the electrical resistance of the coil wire can be reduced.

Preferably, in one embodiment of the coil, the coil wire may include a plurality of coil conductor layers laminated along the axis, and a connection conductor layer that connects the coil conductor layers adjacent to each other in the direction of the axis. Each of the plurality of coil conductor layers may extend along a plane orthogonal to the axis.

According to the embodiment, the length of the coil wire in the direction of the axis can be shortened, compared to when the coil wire is formed to continuously proceed along the axis. In this manner, the length of the coil in the direction of the axis can be shortened.

Preferably, in one embodiment of an inductor component, the inductor component includes an element body including a magnetic material, and the coil disposed inside the element body.

According to the embodiment, since the length of the coil in the direction of the axis can be shortened, the thickness of the inductor component can become thinner to achieve a thinner inductor component.

Preferably, in one embodiment of the inductor component, the element body may be formed of a composite material of a metal magnetic powder and an organic material.

According to the embodiment, DC superimposition characteristics can be improved by the metal magnetic powder. In addition, for example, when the inductor component is incorporated into a substrate, a resin elastically absorbs stress applied from the outside to reduce internal stress applied to the metal magnetic powder. In this manner, it is possible to prevent an inductance value from being degraded due to magnetic distortion.

Preferably, in one embodiment of the inductor component, the insulator may be formed of a composite material of a non-magnetic inorganic material and an organic material, or only the organic material.

According to the embodiment, for example, when the inductor component is incorporated into the substrate, the organic material of the insulator elastically absorbs stress applied from the outside to reduce internal stress applied to the metal magnetic powder. In this manner, it is possible to prevent an inductance value from being degraded due to magnetic distortion.

Preferably, in the embodiment of the inductor component, the inductor component may further include an external terminal provided on an outer surface of the element body and electrically connected to the coil.

Here, the position on the outer surface includes not only a position (on) directly above a portion in contact with the outer surface but also a position (above) separated from the outer surface, that is, an upper side position with another object on the outer surface interposed therebetween or an upper side position at an interval therebetween.

According to the embodiment, since the external terminal is provided, when the inductor component is mounted on a mounting substrate, the inductor component can be easily connected to wires of the mounting substrate.

Preferably, in one embodiment of the inductor component, the inductor component may further include an insulation film disposed between a portion of the external terminal and the outer surface of the element body.

According to the embodiment, insulation properties between the external terminal and the coil are improved.

Preferably, in one embodiment of the inductor component, the outer surface of the element body may include a first surface and a second surface which face each other. The external terminal may include a first external terminal provided on the first surface and a second external terminal provided on the second surface. The first external terminal and the second external terminal may have the same potential.

Here, the position on the first surface includes not only a position (on) directly above a portion in contact with the first surface but also a position (above) separated from the first surface, that is, an upper side position with another object on the first surface interposed therebetween or an upper side position at an interval therebetween. The same applies to the position on the second surface.

According to the embodiment, when the inductor component is incorporated into the substrate to form an electronic circuit, the inductor component can be connected to a circuit of the inductor component from both sides of the first surface and the second surface of the inductor component, and the size of the electronic circuit can be reduced.

Preferably, in one embodiment of an inductor array, the inductor array includes a plurality of the inductor components. The plurality of inductor components are arrayed on the same plane.

According to the embodiment, the thickness of the inductor component can become thinner to achieve a thinner inductor component. Therefore, the thickness of the inductor array can become thinner.

According to the coil, the inductor component, and the inductor array in one aspect of the present disclosure, all of these can become thinner.

### BRIEF DESCRIPTION OF THE DRAWINGS

FIG. 1 is a plan view showing a first embodiment of a coil.

FIG. 2 is a cross-sectional view taken along line A-A in FIG. 1.

FIG. 3A is a cross-sectional view for describing a manufacturing method for the coil.

FIG. 3B is a cross-sectional view for describing a manufacturing method for the coil.

FIG. 4 is a cross-sectional view showing a second embodiment of the coil.

FIG. 5 is a plan view showing a third embodiment of the coil.

FIG. 6 is a cross-sectional view taken along line B-B in FIG. 5.

FIG. 7 is a graph showing a relationship between a ratio Ti3/(Tc+Ti3) and a resistance ratio of a connection conductor layer.

FIG. 8A is a cross-sectional view for describing a manufacturing method for the coil.

FIG. 8B is a cross-sectional view for describing a manufacturing method for the coil.

FIG. 8C is a cross-sectional view for describing a manufacturing method for the coil.

FIG. 8D is a cross-sectional view for describing a manufacturing method for the coil.

FIG. 8E is a cross-sectional view for describing a manufacturing method for the coil.

FIG. 8F is a cross-sectional view for describing a manufacturing method for the coil.

FIG. 8G is a cross-sectional view for describing a manufacturing method for the coil.

FIG. 8H is a cross-sectional view for describing a manufacturing method for the coil.

FIG. 9 is a cross-sectional view showing a fourth embodiment of the coil.

FIG. 10 is a plan view showing an embodiment of an inductor component.

FIG. 11 is a cross-sectional view taken along line A-A in FIG. 10.

FIG. 12 is a cross-sectional view taken along line C-C in FIG. 10.

FIG. 13 is a plan view showing an embodiment of an inductor array.

FIG. 14 is a cross-sectional view showing a state where the inductor array is incorporated into a substrate.

FIG. 15 is a plan view showing an embodiment of the inductor array.

### DESCRIPTION OF THE PREFERRED EMBODIMENTS

Hereinafter, a coil, an inductor component, and an inductor array which are one aspect of the present disclosure will be described in detail with reference to embodiments shown in the drawings. The drawings partially include schematic configurations, and do not reflect actual dimensions or ratios in some cases.

### First Embodiment

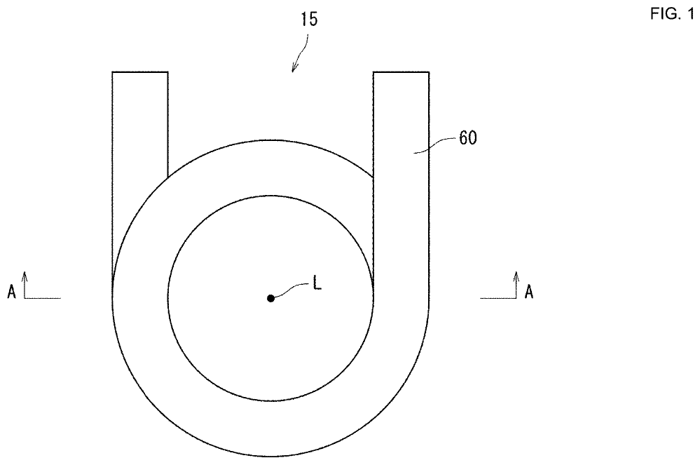

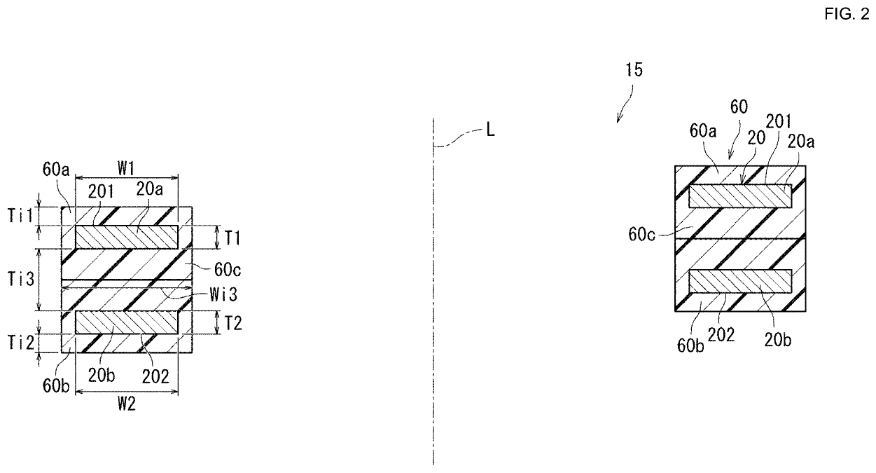

FIG. 1 is a plan view showing a first embodiment of the coil. FIG. 2 is a cross-sectional view taken along line A-A in FIG. 1. As shown in FIGS. 1 and 2, a coil 15 includes a coil wire 20 spirally wound along an axis L, and an insulator 60 that covers at least a portion of the coil wire 20.

The coil wire 20 is formed by spirally winding a flat plate-shaped (flat) conductor along the axis L. That is, the coil wire 20 is formed to continuously proceed along the axis L. The coil wire 20 is formed in a cylindrical shape, and the axis L is also referred to as a center of the cylinder. The coil wire 20 is formed of a metal conductor such as a copper plate.

The insulator 60 is an insulation coating film that covers the coil wire 20. For example, the insulator 60 is formed of a composite material of a non-magnetic inorganic material and an organic material, or only the organic material. For example, the organic material is formed of an epoxy resin, an acrylic resin, a phenol resin, a polyimide resin, a liquid crystal polymer, or a combination thereof. For example, the non-magnetic inorganic material is formed of a filler such as silica. The insulator 60 may be a sintered body such as glass or alumina, or a thin film such as a silicon oxide film, a silicon nitride film, and a silicon oxynitride film. In addition, the insulator 60 may be a magnetic body instead of a non-magnetic body.

As shown in FIG. 2, in a cross section including the axis L, the insulator 60 includes a first insulation portion 60a in contact with a first end surface 201 on one side in the direction of the axis L of the coil wire 20, a second insulation portion 60b in contact with a second end surface 202 on the other side in the direction of the axis L of the coil wire 20, and a third insulation portion 60c located between adjacent turns of the coil wire 20 in the direction of the axis L. In FIG. 2, one side in the direction of the axis L refers to an upper side, and the other side in the direction of the axis L refers to a lower side. The coil wire 20 includes a first wiring portion 20a and a second wiring portion 20b which form the adjacent turns of the coil wire 20 in the direction of the axis L. The first wiring portion 20a is located on the upper side in FIG. 2, and the second wiring portion 20b is located on the lower side in FIG. 2.

The first end surface 201 is a surface facing one side in the direction of the axis L of the coil wire 20 when viewed from one side in the direction of the axis L. That is, the first end surface 201 is a surface exposed to be visually recognizable when viewed from one side in the direction of the axis L when the coil wire 20 is focused on except for the insulator 60. In the present embodiment, the first end surface 201 is an upper end surface. The first end surface 201 is an upper surface of the first wiring portion 20a.

The second end surface 202 is a surface facing the other side of the coil wire 20 in the direction of the axis L when viewed from the other side in the direction of the axis L. That is, the second end surface 202 is a surface exposed to be visually recognizable when viewed from the other side in the direction of the axis L when the coil wire 20 is focused on except for the insulator 60. In the present embodiment, the second end surface 202 is a lower end surface. The second end surface 202 is a lower surface of the second wiring portion 20b.

The first insulation portion 60a is located on one side in the direction of the axis L with respect to the first end surface 201. The second insulation portion 60b is located on the other side in the direction of the axis L with respect to the second end surface 202. The third insulation portion 60c is located between the first wiring portion 20a and the second wiring portion 20b.

At least one thickness in a thickness Ti1 of the first insulation portion 60a and a thickness Ti2 of the second insulation portion 60b is thinner than half of a thickness Ti3 of the third insulation portion 60c. In the embodiment, both the thickness Ti1 and the thickness Ti2 are thinner than half of the thickness Ti3, but at least one thickness in the thickness Ti1 and the thickness Ti2 may be thinner than half of the thickness Ti3.

The thickness is a length in the direction of the axis L. A measuring method for the thickness will be described. In a cross section including the axis L of the coil 15 and intersecting the first end surface 201 and the second end surface 202, intervals of the respective upper surfaces and the respective lower surfaces of the first insulation portion 60a, the second insulation portion 60b, and the third insulation portion 60c in the direction of the axis L are measured at a plurality of optional locations, and average values of the plurality of measured locations are respectively set as the thicknesses. Hereinafter, the measuring method for the thickness is the same as above.

According to the above-described configuration, at least one thickness in the thickness Ti1 of the first insulation portion 60a and the thickness Ti2 of the second insulation portion 60b can become thinner. Therefore, the thickness of the insulator 60 can become thinner, the length of the coil 15 in the direction of the axis L can be reduced, and the coil 15 can become thinner. In addition, without needing to reduce the number of turns of the coil 15, performance of the coil 15 can be secured.

In other words, with regard to insulation of the coil wire 20, insulation between the adjacent turns of the coil wire 20 in the direction of the axis L may be secured, and insulation of the first end surface 201 and the second end surface 202 of the coil wire 20 is unnecessary. In short, in the related art, as a whole, a flat conductor wire is covered with an insulation film having a uniform thickness.

Therefore, the present inventor has focused on the thickness of the insulation film. The present inventor has found the followings. There is room for shortening the length of the coil in the direction of the axis by distinguishing between a portion which needs the thickness of the insulation film and a portion which does not need the thickness of the insulation film. In this manner, the coil becomes thinner by causing the thickness of the unnecessary insulation film to become thinner.

Preferably, in the cross section including the axis L, the thickness Ti1 of the first insulation portion 60a and the thickness Ti2 of the second insulation portion 60b are thinner than half of the thickness Ti3 of the third insulation portion 60c. Accordingly, the thickness of the insulator 60 can become much thinner, the length of the coil 15 in the direction of the axis L can be further shortened, and the coil 15 can become much thinner.

Preferably, in the cross section including the axis L, the thickness Ti3 of the third insulation portion 60c is thinner than the thickness T1 of the first wiring portion 20a, and is thinner than the thickness T2 of the second wiring portion 20b. Accordingly, the thickness Ti3 of the third insulation portion 60c can become thinner. Therefore, the thickness of the insulator 60 can become thinner, and the length of the coil 15 in the direction of the axis L can be shortened. The thickness T1 of the first wiring portion 20a and the thickness T2 of the second wiring portion 20b can become thicker. Therefore, the thickness of the coil wire 20 can become thicker, and electrical resistance of the coil wire 20 can be reduced.

Preferably, in the cross section including the axis L, a width Wi3 of the third insulation portion 60c is equal to or less than 1.5 times a width W1 of the first wiring portion 20a, and is equal to or less than 1.5 times a width W2 of the second wiring portion 20b.

The width is the length orthogonal to the direction of the axis L. The measuring method for the width will be described. The width is an average value when the width is measured in the same cross section as that in the above-described measuring method for the thickness. Accordingly, since the width Wi3 of the third insulation portion 60c can be narrowed, it is possible to reduce a possibility that a magnetic flux of the coil 15 is blocked by the third insulation portion 60c. In addition, the width Wi3 of the third insulation portion 60c is equal to or more than 1.0 times the width W1 of the first wiring portion 20a, and is equal to or more than 1.0 times the width W2 of the second wiring portion 20b. Accordingly, insulation properties between the first wiring portion 20a and the second wiring portion 20b can be secured.

Preferably, in the cross section including the axis L, a ratio Ti3/(Tc+Ti3) between a sum Tc of the thickness T1 of the first wiring portion 20a and the thickness T2 of the second wiring portion 20b and the thickness Ti3 of the third insulation portion 60c is equal to or lower than 30%. Accordingly, the thickness Ti3 of the third insulation portion 60c can become thinner. Therefore, the thickness of the insulator 60 can become thinner, and the length of the coil 15 in the direction of the axis L can be shortened. The thickness T1 of the first wiring portion 20a and the thickness T2 of the second wiring portion 20b can become thicker. Therefore, the thickness of the coil wire 20 can become thicker, and electrical resistance of the coil wire 20 can be reduced.

Next, a manufacturing method for the coil 15 will be described.

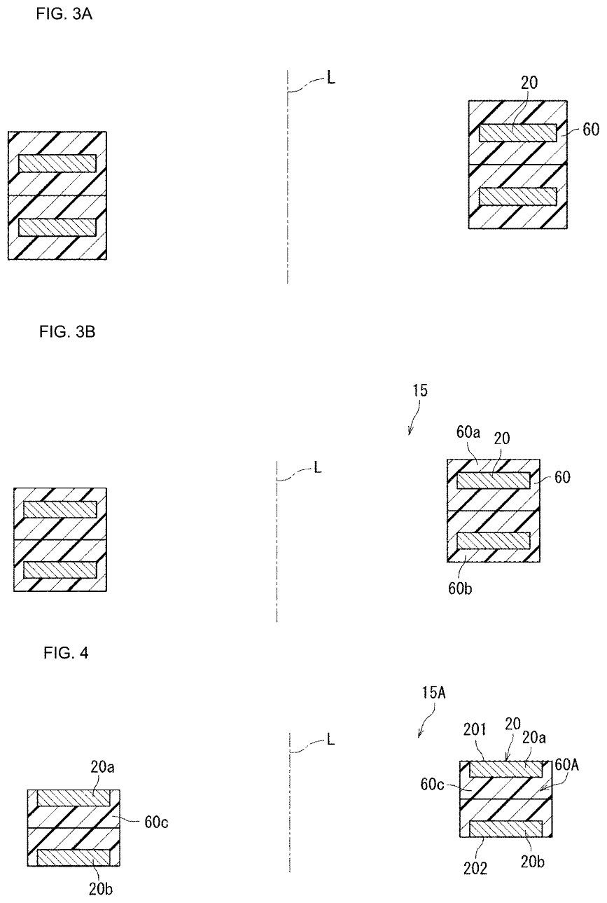

As shown in FIG. 3A, the coil wire 20 coated with the insulator 60 is spirally wound along the axis L. This winding is also called an edge-wise winding. Thereafter, as shown in FIG. 3B, for example, the first insulation portion 60a and the second insulation portion 60b of the insulator 60 became thinner through oxygen ashing. In this manner, the coil 15 is manufactured. The first insulation portion 60a and the second insulation portion 60b may become thinner by using another method other than the ashing.

### Second Embodiment

FIG. 4 is a cross-sectional view showing a second embodiment of the coil. In the second embodiment, a configuration of the insulator is different from that of the first embodiment. The different configuration will be described below. Other configurations are the same as the configurations of the first embodiment. The same reference numerals as those of the first embodiment will be assigned, and description thereof will be omitted.

As shown in FIG. 4, in the coil 15A of the second embodiment, in the cross section including the axis L, an insulator 60A includes a third insulation portion 60c located between adjacent turns of the coil wire 20 in the direction of the axis L without being in contact with at least one of the first end surface 201 on one side in the direction of the axis L of the coil wire 20 and the second end surface 202 on the other side in the direction of the axis L of the coil wire 20.

In the second embodiment, the insulator 60A is not in contact with both the first end surface 201 and the second end surface 202 of the coil wire 20. Specifically, the insulator 60A is not provided with the first insulation portion 60a and the second insulation portion 60b of the first embodiment, and the first end surface 201 and the second end surface 202 of the coil wire 20 are exposed from the insulator 60A. The insulator 60A does not need to be provided with at least one of the first insulation portion 60a and the second insulation portion 60b.

According to the above-described configuration, the insulator 60A does not come into contact with at least one of the first end surface 201 and the second end surface 202 of the coil wire 20. Therefore, the thickness of the insulator 60A can become thinner, and the length of the coil 15A in the direction of the axis L can be shortened.

### Third Embodiment

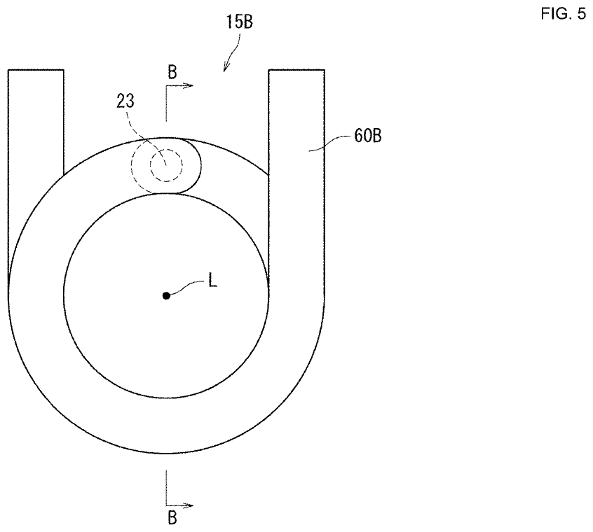

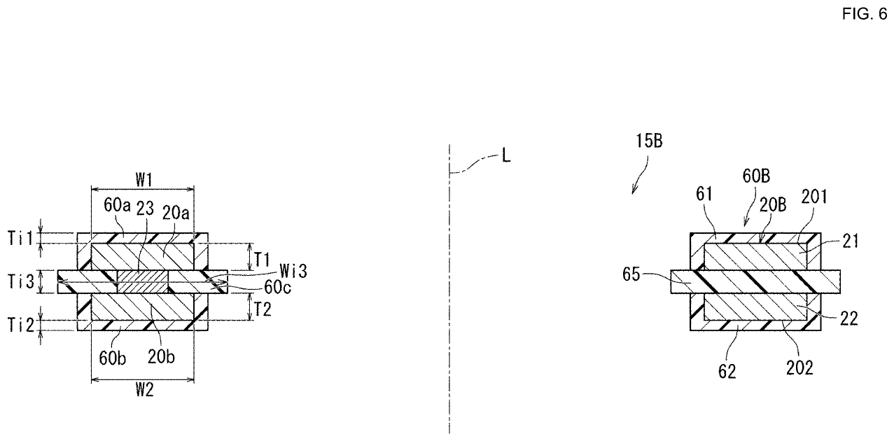

FIG. 5 is a plan view showing a third embodiment of the coil. FIG. 6 is a cross-sectional view taken along line B-B in FIG. 5. In the third embodiment, the configurations of the coil wire and the insulator are different from those of the first embodiment. The different configuration will be described below. Other configurations are the same as the configurations of the first embodiment. The same reference numerals as those of the first embodiment will be assigned, and description thereof will be omitted.

As shown in FIGS. 5 and 6, in the coil 15B of the third embodiment, a coil wire 20B includes a first coil conductor layer 21 and a second coil conductor layer 22 which are laminated along the axis L, and a connection conductor layer 23 that connects the first coil conductor layers 21 and the second coil conductor layers 22 which are adjacent to each other in the direction of the axis L. The first coil conductor layer 21 and the second coil conductor layer 22 respectively extend along a plane orthogonal to the axis L.

Each of the first coil conductor layer 21 and the second coil conductor layer 22 has a spiral shape smaller than one turn. One end of the first coil conductor layer 21 and one end of the second coil conductor layer 22 are connected with the connection conductor layer 23 interposed therebetween. The first coil conductor layer 21 and the second coil conductor layer 22 are connected in series with the connection conductor layer 23 interposed therebetween.

The insulator 60B includes a base insulation layer 65 including a first main surface and a second main surface which face each other, a first insulation layer 61 provided on the first main surface of the base insulation layer 65, and a second insulation layer 62 provided on the second main surface of the base insulation layer 65. The first coil conductor layer 21 is provided on the first main surface of the base insulation layer 65, and is covered with the first insulation layer 61. The second coil conductor layer 22 is provided on the second main surface of the base insulation layer 65, and is covered with the second insulation layer 62. The connection conductor layer 23 penetrates the base insulation layer 65.

In the cross section including the axis L, the first coil conductor layer 21 corresponds to the first wiring portion 20a, and the second coil conductor layer 22 corresponds to the second wiring portion 20b. A portion located on one side in the direction of the axis L with respect to the first end surface 201 in the first insulation layer 61 corresponds to the first insulation portion 60a. A portion located on the other side in the direction of the axis L with respect to the second end surface 202 in the second insulation layer 62 corresponds to the second insulation portion 60b. The base insulation layer 65 corresponds to the third insulation portion 60c.

According to the above-described configuration, the coil wire 20B includes the planar first coil conductor layer 21 and the planar second coil conductor layer 22 which are laminated along the axis L. Therefore, the length of the coil wire 20B in the direction of the axis L can be shortened, compared to when the coil wire is formed to continuously proceed along the axis L. In this manner, the length of the coil in the direction of the axis L can be shortened. That is, a step between an end portion of winding start and an end portion of winding end of the coil wire 20B can be reduced when viewed in a direction orthogonal to the axis L, and the coil wire 20B can become thinner.

Other configurations are the same as those of the first embodiment. However, the following configurations will be described again since the configurations have new advantageous effects in addition to the advantageous effects of the first embodiment.

In the cross section including the axis L, the thickness Ti3 of the third insulation portion 60c is thinner than the thickness T1 of the first wiring portion 20a, and is thinner than the thickness T2 of the second wiring portion 20b. Accordingly, in addition to the advantageous effects of the first embodiment, the thickness Ti3 of the third insulation portion 60c can become thinner. Therefore, the thickness of the connection conductor layer 23 that penetrates the third insulation portion 60c can become thinner. In this manner, electrical resistance of the connection conductor layer 23 can be reduced, and electrical resistance of the coil wire 20B can be reduced.

In the cross section including the axis L, a ratio Ti3/(Tc+Ti3) between a sum Tc of the thickness T1 of the first wiring portion 20a and the thickness T2 of the second wiring portion 20b and the thickness Ti3 of the third insulation portion 60c is equal to or lower than 30%. Accordingly, in addition to the advantageous effects of the first embodiment, the thickness of the third insulation portion 60c can become thinner. Therefore, the thickness of the connection conductor layer 23 penetrating the third insulation portion 60c can become thinner. In this manner, electrical resistance of the connection conductor layer 23 can be reduced, and electrical resistance of the coil wire 20B can be reduced.

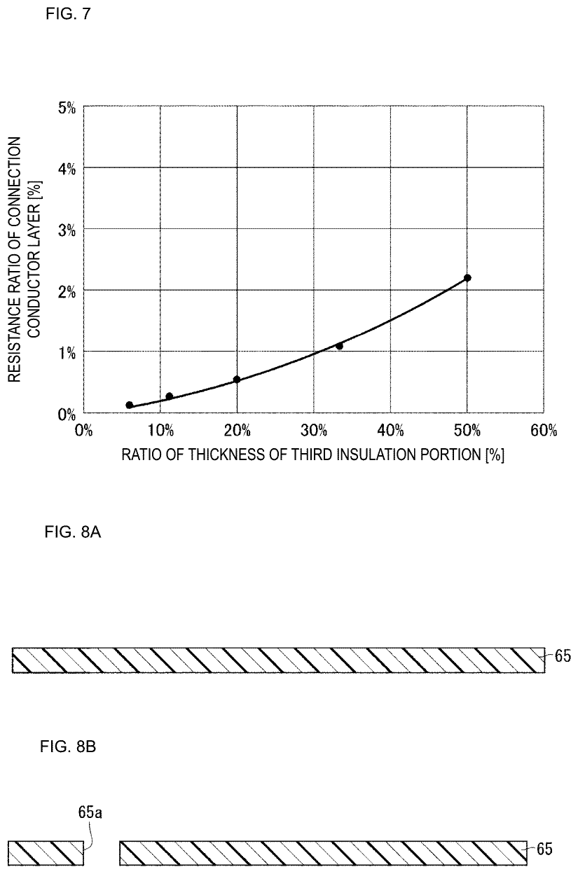

Here, a relationship between the ratio Ti3/(Tc+Ti3) and a resistance ratio of the connection conductor layer will be described. FIG. 7 is a graph showing the relationship between the ratio Ti3/(Tc+Ti3) and the resistance ratio of the connection conductor layer. A horizontal axis indicates the ratio Ti3/(Tc+Ti3) of the thickness, and a vertical axis indicates the resistance ratio of the connection conductor layer.

The resistance ratio of the connection conductor layer refers to a ratio of resistance of the connection conductor layer to total resistance of the coil wire. Each resistance is obtained from each volume and a substance resistivity. In the present embodiment, the material of the coil wire is copper, an inner diameter of the coil wire is 1.6 mm, a wire width of the coil wire is 0.45 mm, the thickness of the coil wire is 0.1 mm, and a diameter of the connection conductor layer is 0.2 mm. The thickness of the connection conductor layer is the same as the thickness of the third insulation portion.

As can be understood from FIG. 7, in the present embodiment, the ratio of the thickness of the third insulation portion is preferably equal to or lower than 30%. Therefore, the resistance ratio of the connection conductor layer is equal to or lower than 1%, and the resistance of the connection conductor layer can be reduced.

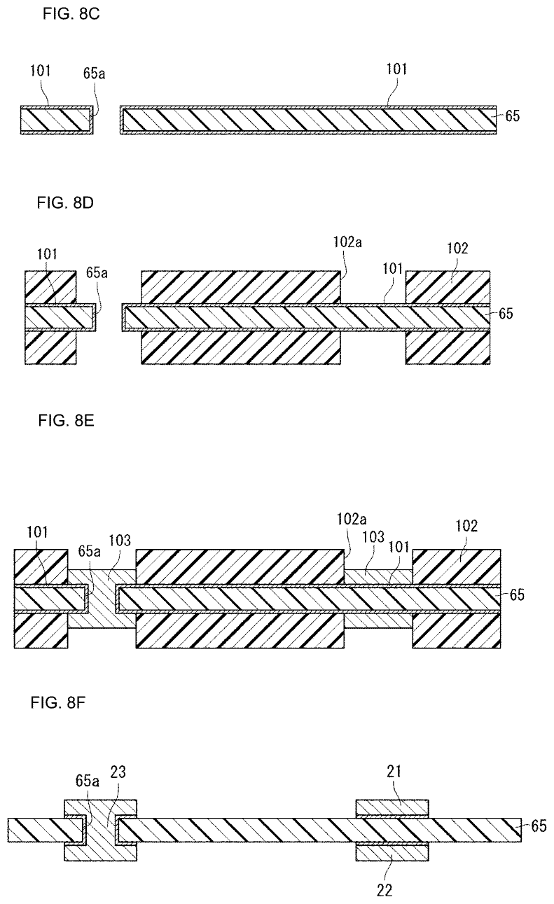

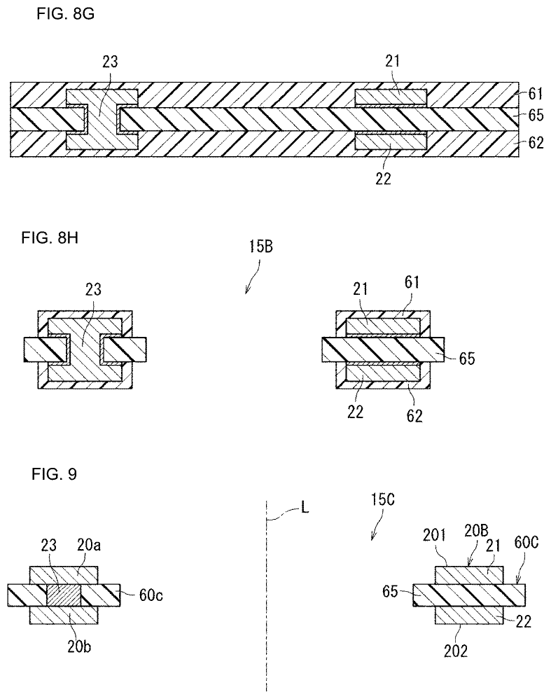

Next, a manufacturing method for the coil 15B will be described. FIGS. 8A to 8H correspond to the cross section taken along line B-B in FIG. 5.

As shown in FIG. 8A, the base insulation layer 65 is prepared, and as shown in FIG. 8B, a portion of the base insulation layer 65 is removed by laser processing to form a through-hole 65a.

As shown in FIG. 8C, a seed layer 101 is formed on a front surface of the base insulation layer 65 through sputtering. The seed layer 101 is formed of Cu/Ti. The seed layer 101 is also formed on an inner surface of the through-hole 65a.

As shown in FIG. 8D, coil pattern portions 102a are

formed on both surfaces of the base insulation layer 65 by using a photoresist 102. As shown in FIG. 8E, a metal film 103 is formed in the through-hole 65a and the coil pattern portion 102a through electrolytic plating.

As shown in FIG. 8F, the photoresist 102 is peeled off, and the exposed seed layer 101 is etched. The first coil conductor layer 21 is formed on the upper surface (first main surface) of the base insulation layer 65 by the seed layer 101 and the metal film 103, the second coil conductor layer 22 is formed on the lower surface (second main surface) of the base insulation layer 65, and the connection conductor layer 23 is formed in the through-hole 65a of the base insulation layer 65.

As shown in FIG. 8G, the first insulation layer 61 is formed on the upper surface of the base insulation layer 65 to cover the first coil conductor layer 21, and the second insulation layer 62 is formed on the lower surface of the base insulation layer 65 to cover the second coil conductor layer 22. As shown in FIG. 8H, the first insulation layer 61, the second insulation layer 62, and the base insulation layer 65 which are located in an inner magnetic path and an outer magnetic path are removed through laser processing to form the coil 15B.

### Fourth Embodiment

FIG. 9 is a cross-sectional view showing a fourth embodiment of the coil. In the fourth embodiment, the configuration of the insulator is different from that in the third embodiment. The different configuration will be described below. Other configurations are the same as those in the third embodiment. The same reference numerals as those in the third embodiment will be assigned, and description thereof will be omitted.

As shown in FIG. 9, in the coil 15C of the fourth embodiment, in the cross section including the axis L, the insulator 60C includes a third insulation portion 60c located between adjacent turns in the direction of the axis L of the coil wire 20B without being in contact with at least one of the first end surface 201 on one side in the direction of the axis L of the coil wire 20B and the second end surface 202 on the other side in the direction of the axis L of the coil wire 20B.

In the fourth embodiment, the insulator 60C is not in contact with both the first end surface 201 and the second end surface 202 of the coil wire 20B. Specifically, the insulator 60C is not provided with the first insulation portion 60a and the second insulation portion 60b of the fourth embodiment, and the first end surface 201 and the second end surface 202 of the coil wire 20B are exposed from the insulator 60C. That is, the insulator 60C is not provided with the first insulation layer 61 and the second insulation layer 62 of the fourth embodiment, and includes the base insulation layer 65. The insulator 60C does not need to be provided with at least one of the first insulation layer 61 and the second insulation layer 62.

According to the above-described configuration, the insulator 60C does not come into contact with at least one of the first end surface 201 and the second end surface 202 of the coil wire 20B. Therefore, the thickness of the insulator 60C can become thinner, and the length of the coil 15A in the direction of the axis L can be shortened.

### Fifth Embodiment

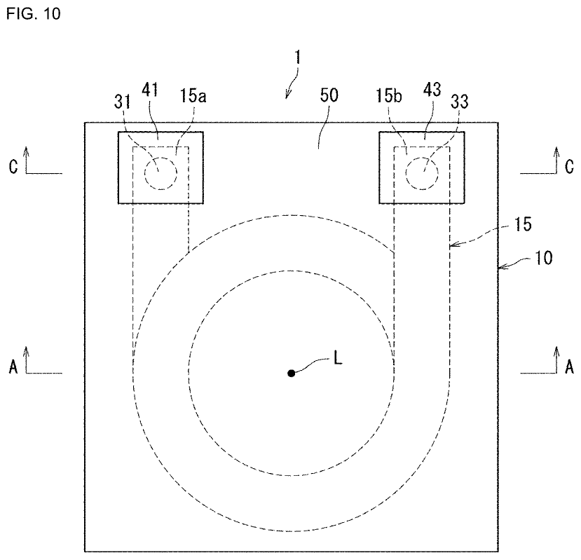

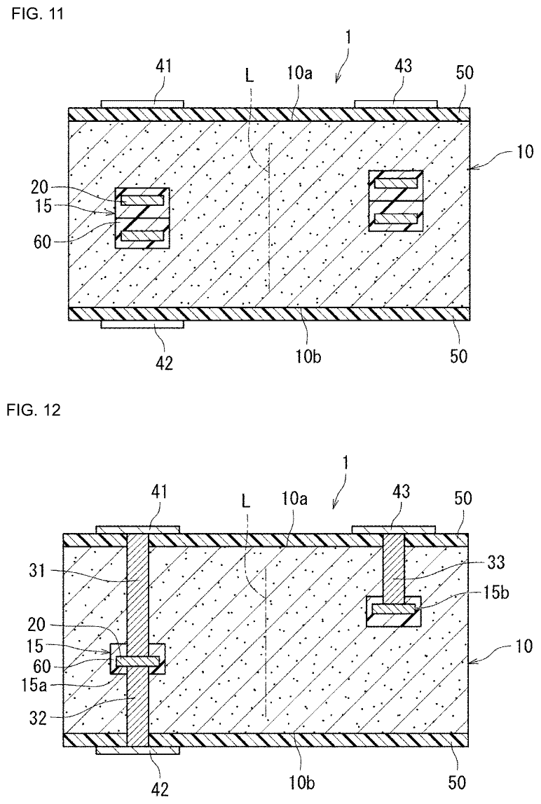

FIG. 10 is a plan view showing an embodiment of an inductor component. FIG. 11 is a cross-sectional view taken along line A-A in FIG. 10. FIG. 12 is a cross-sectional view taken along line C-C in FIG. 10.

For example, an inductor component 1 is mounted on electronic devices such as a personal computer, a DVD player, a digital camera, a TV, a mobile phone, and car electronics, and for example, is a component having a rectangular parallelepiped shape as a whole. However, the shape of the inductor component 1 is not particularly limited, and may be a columnar shape, a polygonal columnar shape, a frustum shape, or a polygonal frustum shape.

As shown in FIGS. 10, 11, and 12, the inductor component 1 includes an element body 10 including a magnetic material, the coil 15 disposed inside the element body 10, a first external terminal 41, a second external terminal 42, and a third external terminal 43 which are provided on an outer surface of the element body 15 and are electrically connected to the coil 15, and an insulation film 50 disposed between each portion of the first external terminal 41, the second external terminal 42, and the third external terminal 43 and the outer surface of the element body 10. The coil 15 corresponds to the coil 15 of the first embodiment, but may be any one coil of the second to fourth embodiments.

According to the above-described configuration, the inductor component 1 includes the coil 15 of the first embodiment. Therefore, the length of the coil 15 in the direction of the axis L can be shortened. In this manner, the thickness of the inductor component 1 can become thinner to achieve a thinner inductor component. Alternatively, since the thickness of the coil 15 becomes thinner, the amount of the magnetic material can be increased, and an inductance value can be improved.

In addition, the inductor component 1 includes the external terminals 41 to 43. Therefore, when the inductor component 1 is mounted on a mounting substrate (not shown), the inductor component 1 can be easily connected to the wire of the mounting substrate.

In addition, the inductor component 1 includes the insulation film 50. Therefore, insulation properties between the external terminals 41 to 43 and the coil 15 are improved. In addition, the insulation film 50 is disposed in an outer side portion of the element body 10. Therefore, the insulation film 50 does not hinder a magnetic flux of the coil 15. In contrast, when the insulation film is provided inside the element body to secure insulation properties between the coil and the external terminal, the insulation film hinders the magnetic flux of the coil.

As shown in FIGS. 10, 11, and 12, the element body 10 is formed of a composite material of a metal magnetic powder and an organic material. For example, the metal magnetic powder is formed of FeSi-based alloy such as FeSiCr, Fe-based alloy such as FeCo-based alloy and NiFe, or an amorphous alloy thereof. For example, the organic material is formed of an epoxy resin, an acrylic resin, a phenol resin, a polyimide resin, a liquid crystal polymer, or a combination thereof.

According to the above-described configuration, DC superimposition characteristics can be improved by the metal magnetic powder. In addition, for example, when the inductor component 1 is incorporated into a substrate, the resin elastically absorbs stress applied from the outside to reduce internal stress applied to a metal magnetic powder. In this manner, it is possible to prevent an inductance value from being degraded due to magnetic distortion. In some cases, the element body does not need to include an organic resin such as ferrite or a sintered body of a magnetic powder.

As described above in the first embodiment, the insulator 60 of the coil 15 is formed of a composite material of a non-magnetic inorganic material and an organic material, or only the organic material. Accordingly, for example, when the inductor component 1 is incorporated into the substrate, the organic material of the insulator 60 elastically absorbs stress applied from the outside to reduce internal stress applied to the metal magnetic powder. In this manner, it is possible to prevent an inductance value from being degraded due to magnetic distortion.

The outer surface of the element body 10 includes a first surface 10a and a second surface 10b which face each other. The first surface 10a and the second surface 10b are orthogonal to the axis L of the coil 15. In the present embodiment, the first surface 10a is the upper surface, and the second surface 10b is the lower surface.

The coil 15 includes a first end portion 15a which is a lowermost end on the second surface 10b side and a second end portion 15b which is an uppermost end on the first surface 10a side. A first extended wire 31 and a second extended wire 32 are connected to the coil wire 20 of the first end portion 15a. A third extended wire 33 is connected to the coil wire 20 of the second end portion 15b.

The first extended wire 31 extends from the first end portion 15a toward the first surface 10a side along the axis L. The first extended wire 31 is exposed from the first surface 10a and the insulation film 50. The second extended wire 32 extends along the axis L from the first end portion 15a toward the second surface 10b side. The second extended wire 32 is exposed from the second surface 10b and the insulation film 50. The third extended wire 33 extends from the second end portion 15b toward the first surface 10a side along the axis L. The third extended wire 33 is exposed from the first surface 10a and the insulation film 50.

The first external terminal 41 is provided on the first surface 10a, and is connected to the first extended wire 31. The insulation film 50 is disposed between a portion of the first external terminal 41 and the first surface 10a. The second external terminal 42 is provided on the second surface 10b, and is connected to the second extended wire 32. The insulation film 50 is disposed between a portion of the second external terminal 42 and the second surface 10b. The third external terminal 43 is provided on the first surface 10a, and is connected to the third extended wire 33. The insulation film 50 is disposed between a portion of the third external terminal 43 and the first surface 10a.

The first external terminal 41 and the second external terminal 42 have the same potential. Accordingly, when the inductor component 1 is incorporated into the substrate to form an electronic circuit, the inductor component 1 can be connected to a circuit from both sides of the first surface 10a and the second surface 10b of the inductor component 1, and the size of the electronic circuit can be reduced.

In the inductor component according to the present embodiment, the second external terminal 42 and the second extended wire 32 do not need to be provided, and the first external terminal 41 and the third external terminal 43 may be provided. In addition, the third external terminal 43 may be provided on the second surface 10b instead of the first surface 10a. In addition, without providing the insulation film 50, the first external terminal 41 and the third external terminal 43 may be brought into contact with the first surface 10a, and the second external terminal 42 may be brought into contact with the second surface 10b.

### Sixth Embodiment

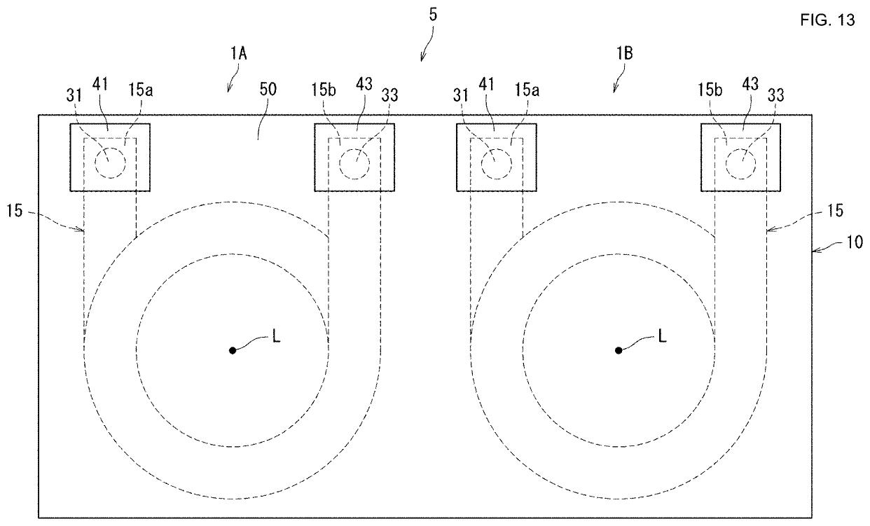

FIG. 13 is a plan view showing an embodiment of an inductor array. As shown in FIG. 13, an inductor array 5 includes a first inductor component 1A and a second inductor component 1B. Each of the first inductor component 1A and the second inductor component 1B has the same configuration as the inductor component 1 of the fifth embodiment except that the second extended wire 32 and the second external terminal 42 are not provided.

The first inductor component 1A and the second inductor component 1B are arrayed on the same plane orthogonal to the axis L so that the axes L of the respective coils 15 are parallel to each other. Specifically, the first inductor component 1A and the second inductor component 1B are electrically independent. The first external terminal 41 and the third external terminal 43 of the first inductor component 1A and the first external terminal 41 and the third external terminal 43 of the second inductor component 1B are linearly arrayed along a direction orthogonal to the axis L.

According to the above-described configuration, the inductor components 1A and 1B having the same configuration as that of the inductor component 1 of the fifth embodiment are provided. Therefore, the thickness of the inductor components 1A and 1B can become thinner to achieve a thinner inductor array. As a result, the thickness of the inductor array 5 can become thinner.

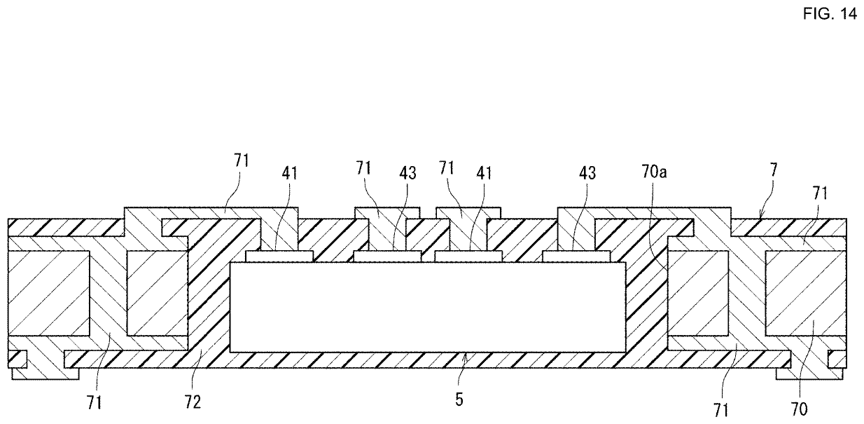

FIG. 14 is a cross-sectional view showing a state where the inductor array 5 is incorporated into the substrate 7. In FIG. 14, for convenience, the inductor array 5 is not hatched. As shown in FIG. 14, the inductor array 5 is incorporated into the substrate 7. The substrate 7 includes a core material 70, a wiring portion 71, and a resin member 72. The inductor array 5 is disposed inside a through-hole 70a of the core material 70. The resin member 72 seals the inductor array 5 and the substrate 7. The wiring portion 71 is provided to extend to the core material 70 and the resin member 72, and is connected to the external terminals 41 and 43 of the inductor array 5. In this manner, the thickness of the inductor array 5 can become thinner. Therefore, the thickness of the substrate 7 can become thinner.

### Seventh Embodiment

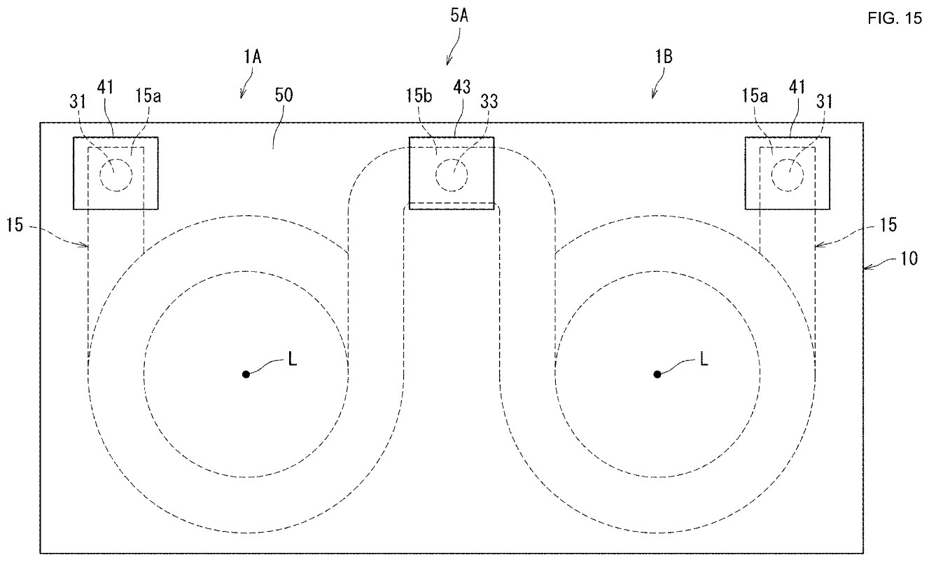

FIG. 15 is a plan view showing an embodiment of the inductor array. A seventh embodiment is different from the sixth embodiment in a disposition of the coil. The different configuration will be described below. Other configurations are the same as those in the sixth embodiment. The same reference numerals as those in the sixth embodiment will be assigned, and description thereof will be omitted.

As shown in FIG. 15, in an inductor array 5A, the first inductor component 1A and the second inductor component 1B are electrically connected in series. Specifically, the second end portion 15b of the coil 15 of the first inductor component 1A and the second end portion 15b of the coil 15 of the second inductor component 1B are common members. That is, the first inductor component 1A and the second inductor component 1B have the common third extended wire 33 and the common third external terminal 43. In this way, the inductor array 5A includes two sets of the first extended wire 31 and the first external terminal 41, and one set of the third extended wire 33 and the third external terminal 43.

According to the above-described configuration, in addition to the advantageous effects of the inductor array 5 of the sixth embodiment, the size of the inductor array 5A can be reduced by using the members in common.

The present disclosure is not limited to the above-described embodiments, and can be modified within the scope not departing from the concept of the present disclosure. For example, respective characteristic points of the first to seventh embodiments may be combined in various ways.

In the second embodiment, the coil wire is formed of the coil conductor layer having two layers, but may be formed of the coil conductor layer having three or more layers. In the second embodiment, the coil conductor layers having the two layers are connected in series, but the coil conductor layers having the two layers may be connected in parallel.

In the fifth embodiment, the coil is applied to the inductor component, but the coil may be applied to an electronic component such as a transformer. In this case, an inner magnetic path of the coil may be an air core.

In the sixth embodiment, the inductor array uses only the coil of the first embodiment, but the coil of the first embodiment and the coil of the second embodiment may be used, or only the coil of the second embodiment may be used. In addition, the inductor array may include three or more inductor components.

In the sixth embodiment, the first inductor component and the second inductor component are arrayed on the same plane orthogonal to the axis so that the axes of the respective coils are parallel to each other. However, as long as the first inductor component and the second inductor component are arrayed on the same plane, the axes of the respective coils do not need to be parallel to each other.

### REFERENCE SIGNS LIST

1 inductor component
1A first inductor component
1B second inductor component
5, 5A inductor array
7 substrate
10 Element body
10a first surface
10b second surface
15, 15A, 15B, 15C coil
15a first end portion
15b second end portion
20, 20B coil wire
20a first wiring portion
20b second wiring portion
201 first end surface
202 second end surface
21 first coil conductor layer
22 second coil conductor layer
23 connection conductor layer
31 to 33 first to third extended wires
41 to 43 first to third external terminals
50 insulation film
60, 60A, 60B, 60C insulator
60a to 60c first to third insulation portions
61 first insulation layer
62 second insulation layer
65 base insulation layer
L axis of coil
T1 thickness of first wiring portion
T2 thickness of second wiring portion
Ti1 thickness of first insulation portion
Ti2 thickness of second insulation portion
Ti3 thickness of third insulation portion
W1 width of first wiring portion
W2 width of second wiring portion
Wi3 width of third insulation portion

1. A coil comprising:
a coil wire spirally wound along an axis; and
an insulator that covers at least a portion of the coil wire,
wherein in a cross section including the axis, the insulator includes:
a first insulation portion in contact with a first end surface of the coil wire on a first side in a direction of the axis of the coil wire,
a second insulation portion in contact with a second end surface of the coil wire on a second side in the direction of the axis of the coil wire, and
a third insulation portion between adjacent turns in the direction of the axis of the coil wire, wherein
at least one of a first thickness of the first insulation portion and a second thickness of the second insulation portion is thinner than half of a third thickness of the third insulation portion.

2. The coil according to claim 1,
wherein in the cross section including the axis, the coil wire includes a first wiring portion and a second wiring portion which form adjacent turns of the coil wire in the direction of the axis, and
a thickness Ti3 of the third insulation portion between the first wiring portion and the second wiring portion is thinner than a thickness T1 of the first wiring portion, and is thinner than a thickness T2 of the second wiring portion.

3. The coil according to claim 1,
wherein in the cross section including the axis, the coil wire includes a first wiring portion and a second wiring portion which form adjacent turns of the coil wire in the direction of the axis, and
a width Wi3 of the third insulation portion between the first wiring portion and the second wiring portion is equal to or less than 1.5 times a width W1 of the first wiring portion, and is equal to or less than 1.5 times a width W2 of the second wiring portion.

4. The coil according to claim 1,
wherein in the cross section including the axis, the coil wire includes a first wiring portion and a second wiring portion which form adjacent turns of the coil wire in the direction of the axis, and
a ratio Ti3/(Tc+Ti3) between a sum Tc of a thickness T1 of the first wiring portion and a thickness T2 of the second wiring portion and a thickness Ti3 of the third insulation portion between the first wiring portion and the second wiring portion is equal to or lower than 30%.

5. The coil according to claim 1,
wherein the coil wire includes a plurality of coil conductor layers laminated along the axis, and a connection conductor layer that connects the coil conductor layers adjacent to each other in the direction of the axis, and
each of the plurality of coil conductor layers extends along a plane orthogonal to the axis.

6. An inductor component comprising:
an element body including a magnetic material; and
the coil according to claim 1 inside the element body.

7. The inductor component according to claim 6, further comprising:
an external terminal on an outer surface of the element body and electrically connected to the coil.

8. An inductor array comprising:
a plurality of the inductor components according to claim 7,
wherein the plurality of inductor components are arrayed on the same plane.

9. A coil comprising:
a coil wire spirally wound along an axis; and
an insulator that covers at least a portion of the coil wire,
wherein in a cross section including the axis, the insulator includes an insulation portion between adjacent turns in a direction of the axis of the coil wire without being in contact with at least one of a first end surface on a first side of the coil wire in the direction of the axis and a second end surface on a second side of the coil wire in the direction of the axis.

10. The coil according to claim 9,
wherein in the cross section including the axis, the coil wire includes a first wiring portion and a second wiring portion which form adjacent turns of the coil wire in the direction of the axis, and
a thickness Ti3 of the insulation portion between the first wiring portion and the second wiring portion is thinner than a thickness T1 of the first wiring portion, and is thinner than a thickness T2 of the second wiring portion.

11. The coil according to claim 9,
wherein in the cross section including the axis, the coil wire includes a first wiring portion and a second wiring portion which form adjacent turns of the coil wire in the direction of the axis, and
a width Wi3 of the insulation portion between the first wiring portion and the second wiring portion is equal to or less than 1.5 times a width W1 of the first wiring portion, and is equal to or less than 1.5 times a width W2 of the second wiring portion.

12. The coil according to claim 9,
wherein in the cross section including the axis, the coil wire includes a first wiring portion and a second wiring portion which form adjacent turns of the coil wire in the direction of the axis, and
a ratio Ti3/(Tc+Ti3) between a sum Tc of a thickness T1 of the first wiring portion and a thickness T2 of the second wiring portion and a thickness Ti3 of the insulation portion between the first wiring portion and the second wiring portion is equal to or lower than 30%.

13. The coil according to claim 9,
wherein the coil wire includes a plurality of coil conductor layers laminated along the axis, and a connection conductor layer that connects the coil conductor layers adjacent to each other in the direction of the axis, and
each of the plurality of coil conductor layers extends along a plane orthogonal to the axis.

14. An inductor component comprising:
an element body including a magnetic material; and
the coil according to claim 9 inside the element body.

15. The inductor component according to claim 14, wherein the element body is a composite material of a metal magnetic powder and an organic material.

16. The inductor component according to claim 15, wherein the insulator is a composite material of a non-magnetic inorganic material and an organic material, or only the organic material.

17. The inductor component according to claim 14, further comprising:
an external terminal on an outer surface of the element body and electrically connected to the coil.

18. The inductor component according to claim 17, further comprising:
an insulation film between a portion of the external terminal and the outer surface of the element body.

19. The inductor component according to claim 17,
wherein the outer surface of the element body includes a first surface and a second surface which face each other,
the external terminal includes a first external terminal on the first surface and a second external terminal on the second surface, and
the first external terminal and the second external terminal have the same potential.

20. An inductor array comprising:
a plurality of the inductor components according to claim 14,
wherein the plurality of inductor components are arrayed on the same plane.
